(19) United States
(12) Patent Application Publication
(10) Pub. No.: US 2009/0176320 A1
(43) Pub. Date: Jul. 9, 2009

(54) METHOD FOR FABRICATION OF FLOATING GATE IN SEMICONDUCTOR DEVICE

(76) Inventors: Jin-Ho Kim, Gincheon-si (KR); Ki-Min Lee, Cheongju-si (KR)

Correspondence Address: SHERR & VAUGHN, PLLC, 620 HERNDON PARKWAY, SUITE 200, HERNDON, VA, 20170, US

(21) Appl. No.: 12/344,504

(22) Filed: Dec. 27, 2008

(30) Foreign Application Priority Data
Dec. 27, 2007 (KR) 10-2007-0138317

(51) Int. Cl. H01L 21/66; H01L 21/28; H01L 21/3065

(52) U.S. Cl. 438/8; 438/585; 438/712; 257/E21.19; 257/E21.218; 257/E21.528

(57) ABSTRACT

A method for manufacturing a floating gate includes: forming a tunnel oxide film on a semiconductor substrate; forming a polysilicon layer on a surface of the tunnel oxide film; forming a photosensitive film pattern on a surface of the polysilicon layer; depositing a by-product on the photosensitive film to generate a by-product mask; and using the by-product mask as an etching mask to etch the polysilicon layer, completing fabrication of the floating gate. The polysilicon layer may be etched by a simplified process using a by-product mask so as to fabricate the floating gate, the etch rate of the polysilicon layer may be increased to improve productivity, poly bridge problems may be eliminated, and total amount of a gas used in etching the polysilicon layer may be reduced, resulting in an increase in hardware margin and a decrease in the amount of the gas used in this method.

The present application claims priority under 35 U.S.C. 119 to Korean Patent Application No. 10-2007-0138317 (filed on Dec. 27, 2007), which is hereby incorporated by reference in its entirety.

### BACKGROUND

Generally, a flash memory has a gate pattern structure wherein a tunnel oxide layer, a floating gate, a dielectric substance, and a control gate are stacked in sequence. FIG. 1 illustrates a related method for fabrication of a floating gate that helps reveal an etch rate, in which a transversal (or horizontal) axis (X axis) and a longitudinal axis (Y axis) represent coordinates for a wafer and the center of the coordinates is defined as (0,0).

Uniformity of etch rates in etching polysilicon (sometimes, referred to as “polycrystalline silicon”) by a reactive ion etching (RIE) process to form a floating gate ranges from 5 to 6%, as shown in FIG. 1. As such, the floating gate formed by a this method has a considerable variation in critical points (CD).

FIG. 2 is a graph illustrating a wavelength band at which an investigation was conducted into application of an end point detection (EPD) process for etching polysilicon in a related method for fabrication of a floating gate. In that graph, the horizontal axis represents time while the vertical axis represents intensity at a certain wavelength.

As for the related method for fabricating a floating gate, a time etching process may be used to etch polysilicon in order to produce the floating gate, in place of an EPD process. This is because an etching mask for forming a floating gate has a pattern with dense intervals (or narrow spaces), which in turn, has too small of an intensity at a wavelength 10 to detect an end point (EP), as illustrated in FIG. 2. In other word, a wavelength band applied to etch a polysilicon layer may include 3850 Å, 4405 Å and/or 3650 Å, at which an intensity is relatively small and uniform, and thus, using an EPD process with this method for fabricating a floating gate is substantially ineffective.

Consequently, a polysilicon layer may be subjected to etching by a time etching process. The time etching process may be ineffective because of etching equipment or preceding processes, so that a polysilicon layer may be insufficiently etched and/or the etching condition of the polysilicon layer may not be detected. As a result, problems may arise in relation to a poly bridge of the floating gate.

In addition, the related method for fabrication of a floating gate often uses an oxide hard mask to etch a polysilicon layer. Accordingly, the etching process is relatively complex. Furthermore, the related method for fabrication of a floating gate generally uses only HBr gas under high pressure to etch polysilicon, thus exhibiting a low polysilicon layer etch rate, and contributing to decreased productivity.

### SUMMARY

Embodiments relate to a method for fabrication of a floating gate in a semiconductor device that may substantially overcome poly bridge problems, maximize the margin of hardware equipment, and fabricate a floating gate with a high etch rate.

Embodiments relate to a method for fabricating a floating gate in a semiconductor device that includes: forming a tunnel oxide film on a semiconductor substrate; forming a polysilicon layer on a top surface of the tunnel oxide film; forming a photosensitive film pattern, which is used to fabricate a floating gate, on a top surface of the polysilicon layer; depositing a by-product on the photosensitive film to generate a by-product mask; and using the by-product mask as an etching mask to etch the polysilicon layer, completing fabrication of the floating gate.

Embodiments relate to a method for fabricating a floating gate in a semiconductor device that may use a by-product mask to etch a polysilicon layer in order to simplify production processes and may use Cl₂ gas as well as an HBr gas under low pressure to maximize the etch rate of a polysilicon layer and maximize productivity.

Embodiments include a polysilicon layer that may be etched by an EPD process instead of a time etching process so as to minimize poly bridge problems and to minimize the total amount of gases used in etching the polysilicon layer, resulting in maximization of a hardware margin.

### DRAWINGS

FIG. 1 illustrates a representation of an etch rate of a related method for fabrication of a floating gate.

FIG. 2 illustrates a graph for wavelength spectrums at which an investigation was conducted into applicability of an EPD process for etching polysilicon in a related method for fabrication of a floating gate.

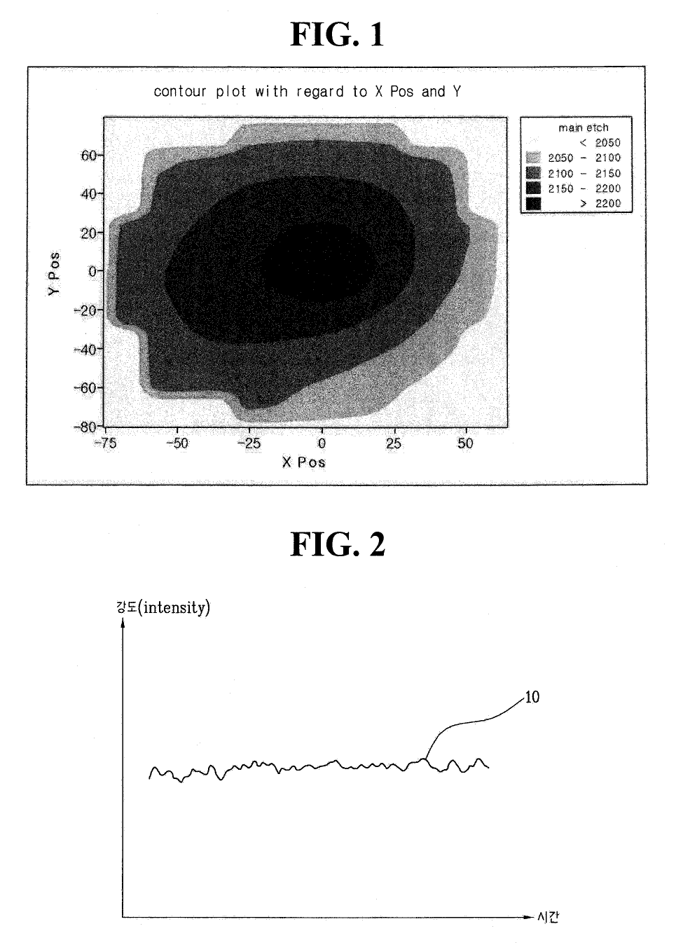

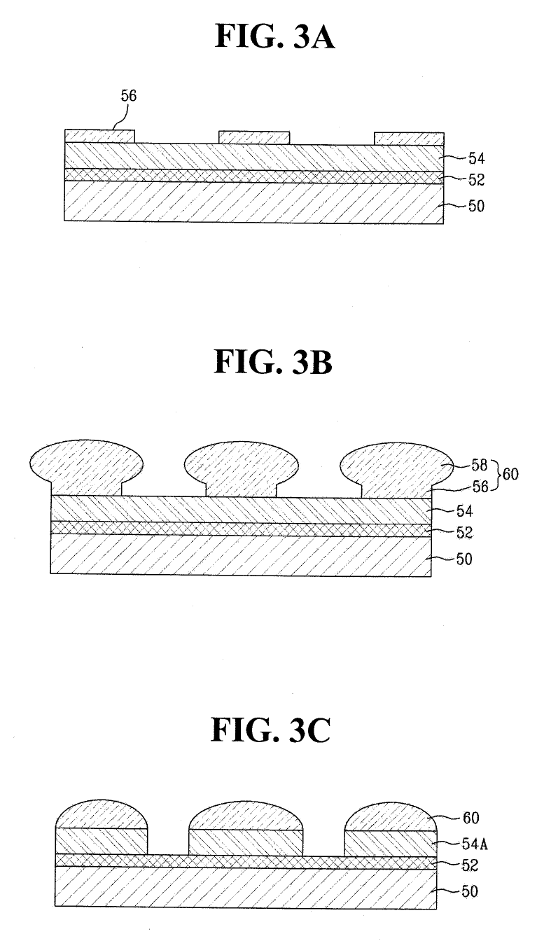

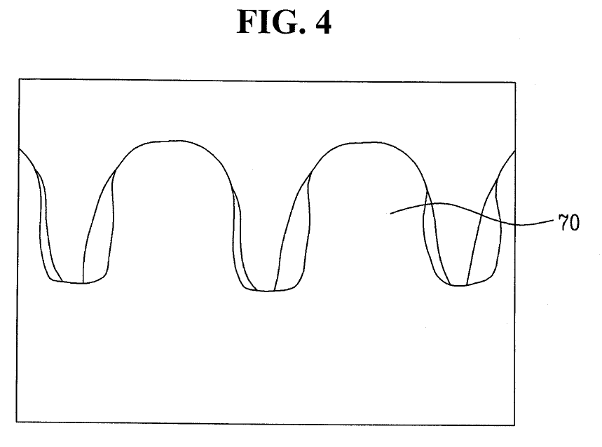

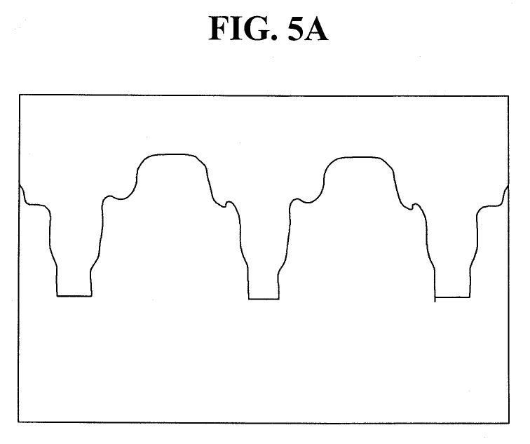

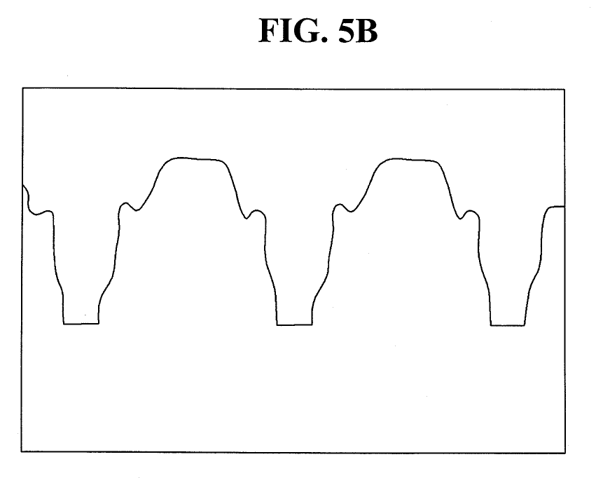

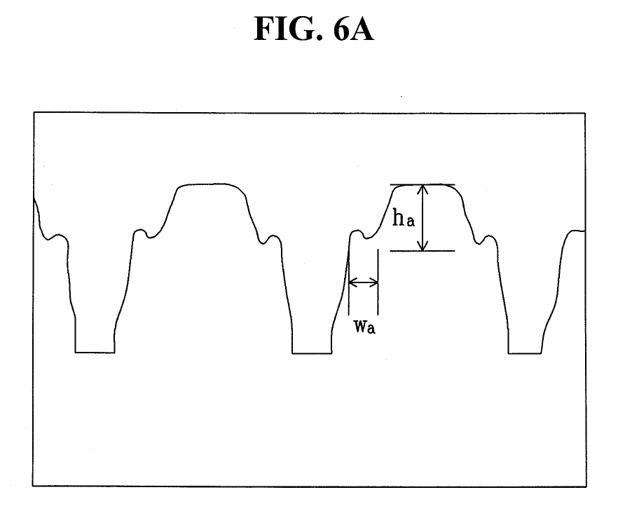

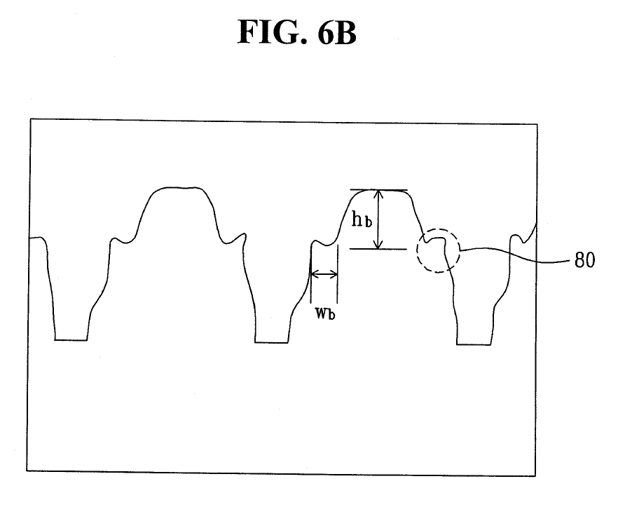

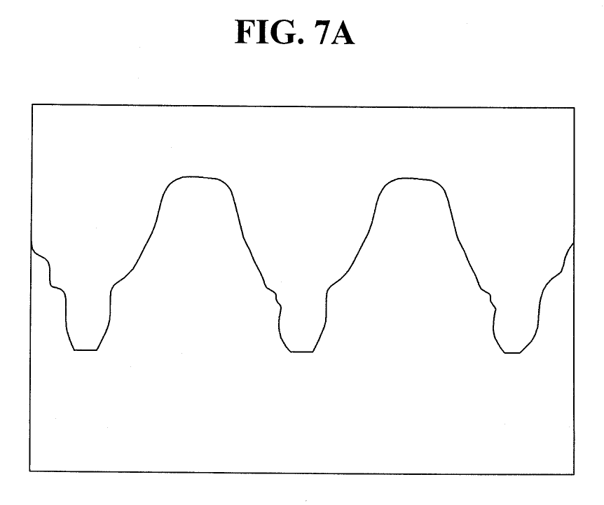

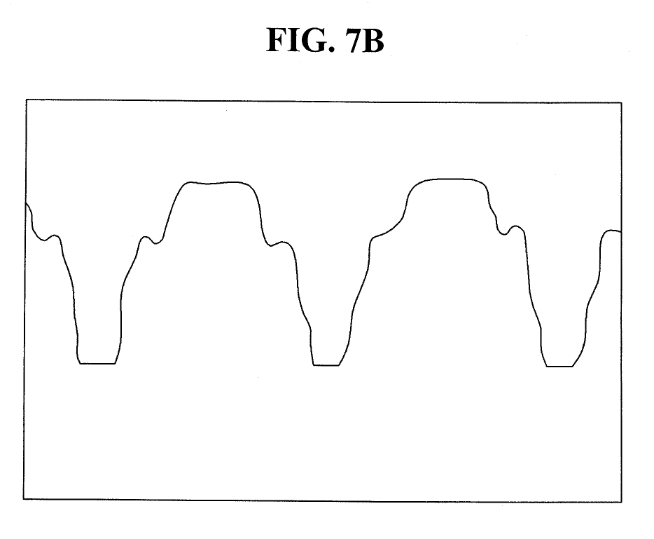

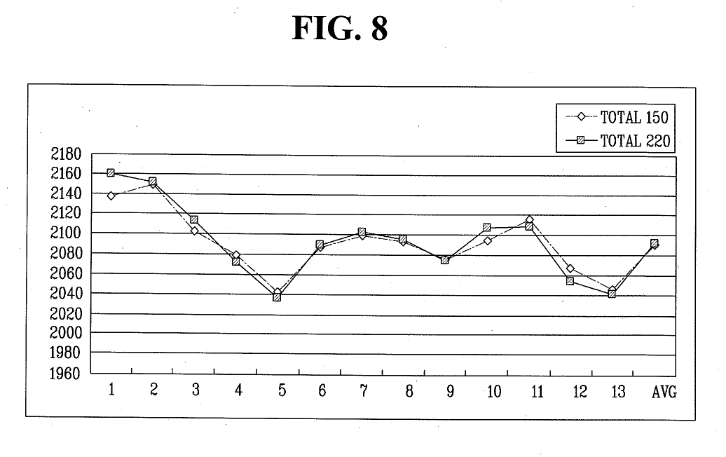

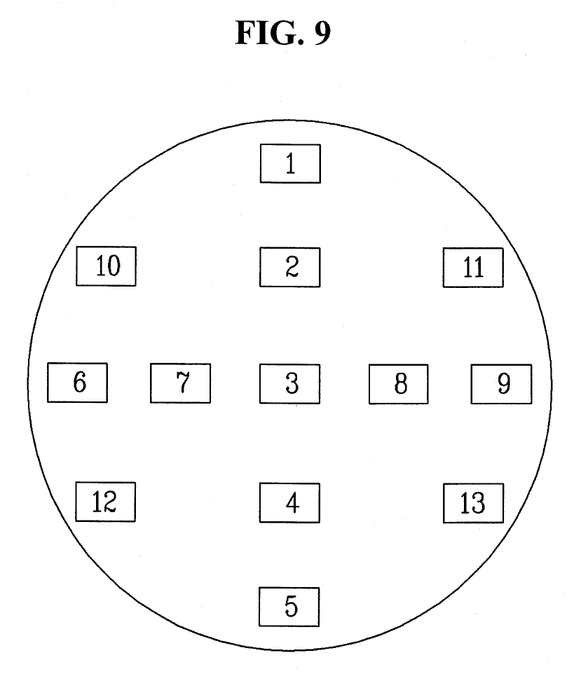

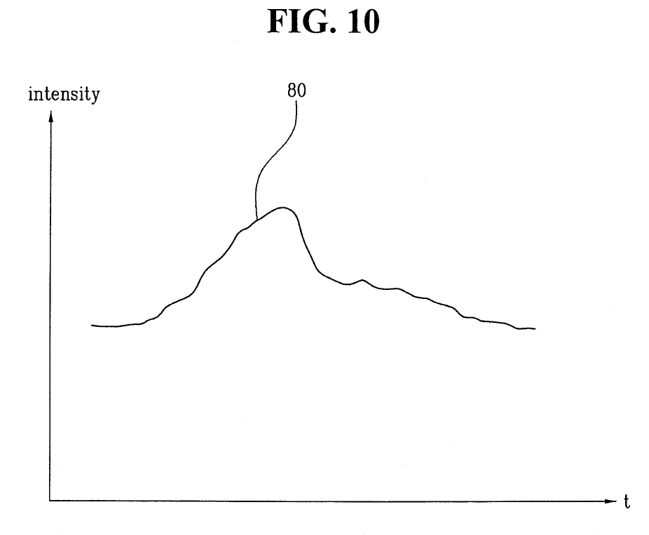

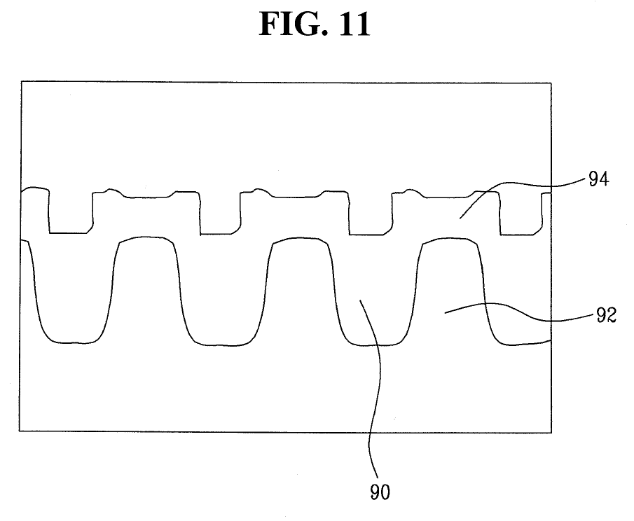

Example FIGS. 3A to 3C are cross-sectional views illustrating a method for fabrication of a floating gate according to embodiments.

Example FIG. 4 is a cross-sectional view illustrating a semiconductor device being treated by a BT etching process in a method for fabricating a floating gate according to embodiments.

Example FIGS. 5A and 5B are cross-sectional views showing a floating gate when each ME process is performed under different atmospheric pressure such as, for example about 5 mT and about 8 mT, respectively, in accordance with embodiments.

Example FIGS. 6A and 6B are cross-sectional views showing a floating gate when each ME process is performed with a different bias power such as, for example, about 130 W and about 115 W, respectively, in accordance with embodiments.

Example FIGS. 7A and 7B are cross-sectional views showing a floating gate when each ME process is performed with different amounts of Cl₂ gas such as, for example, about 68% and about 30%, respectively, in accordance with embodiments.

Example FIG. 8 illustrates graphs for polysilicon etch rates in an ME process, in accordance with embodiments.

Example FIG. 9 illustrates measurement points on a wafer, which are shown in FIG. 8.

Example FIG. 10 illustrates a graph of signal intensity to time at a particular wavelength such as, for example, about 426.5 nm, in accordance with embodiments.

Example FIG. 11 is a view showing a semiconductor device resulting from a method for fabricating a floating gate according to embodiments.

### DESCRIPTION

Example FIGS. 3A to 3C are cross-sectional views illustrating a method for fabrication of a floating gate according to embodiments. Referring to example FIG. 3A, a tunnel oxide layer 52 may be formed on, or over, a semiconductor substrate 50. A polysilicon layer 54 may be formed on, or over, a top surface of the tunnel oxide layer 52. A photosensitive film pattern 56 for fabricating a floating gate may be formed on, or over, a top surface of the polysilicon layer 54.

After a photoresist is applied over a top surface of the polysilicon layer 54, the photoresist may be hardened and etched so as to form a photosensitive film pattern that exposes a region on which the floating gate may be fabricated. Referring to FIG. 3B, a by-product (or a polymer) 58 may be deposited on, or over, the photosensitive film pattern 56 to form a by-product capping mask (BCM) 60. The by-product 58 may also be deposited on lateral sides of the photosensitive film pattern 56 and, optionally, on, or over, a top surface of the photosensitive film pattern 56. One reason for forming the by-product 58 on the lateral sides of the photosensitive film pattern 56 is that a polysilicon layer 54 formed below the lateral sides would be protected from being removed when the polysilicon layer 54 is subjected to a subsequent etching process.

According to embodiments, a natural oxide layer, which is drained out when the BCM 60 is formed and remains on the polysilicon layer 54, may be etched and removed. For instance, an RIE process may be used to etch and remove the natural oxide layer. The etching process for removing a natural oxide layer may be referred to, herein, as a break through (BT) process.

Example FIG. 4 is a cross-sectional view of a semiconductor device after it was treated by a BT etching process in a method for fabricating a floating gate according to embodiments. Referring to example FIG. 4, another BCM 70 obtained after the BT etching process is performed.

The BT etching process may be performed, for example, using Ar gas as well as CF₄ gas. Using both the Ar gas and the CF₄ gas, the BT etching process may assist in maximizing uniformity. In addition, increasing the total amount of the gases compared to that in a related BT etching process may ensure a margin of control with equipment operating under low pressure. For instance, an RIE process using Ar gas may remove the natural oxide layer. Referring to example FIG. 3C, using the BCM 60 as an etching mask, the polysilicon layer 54 may be etched to form a floating gate 54A. The etching process for fabricating the floating gate 54A may be referred to, herein, as a main etching (ME) process.

For instance, an RIE process may be used to etch the polysilicon layer 54 and form the floating gate 54A. Example FIGS. 5A and 5B are cross-sectional views of a floating gate when an ME process is performed under different atmospheric pressures, respectively. The ME process for fabricating the floating gate shown in example FIG. 5A may be performed under an atmospheric pressure lower than that of the ME process shown in example FIG. 5B.

Also, the mask 56 shown in example FIG. 3A has an open space with a relatively small CD, thus exhibiting a low aspect ratio. In other words, in order to attain vertical etching (of the polysilicon layer), a mean free path may be extended to maximally transport energy of ions. However, when the atmospheric pressure in the ME process is relatively high, a residence time of the ions may be prolonged, leading to increased loss in an etching mask.

From example FIGS. 5A and 5B, it can be seen that the floating gate may be formed at an angle if the ME process is performed under relatively high pressure, although both cases shown in example FIGS. 5A and 5B show substantially similar poly-etch rates. Therefore, the pressure in the ME process may be decreased. According to embodiments, the pressure in an etching process (that is, ME process) may be determined such that an etch selectivity between the polysilicon layer 54 and the BCM 60 is enhanced.

Example FIGS. 6A and 6B are cross-sectional views showing a floating gate when an ME process is performed with different bias powers, respectively. The bias power in the ME process for fabricating the floating gate shown in example FIG. 6A may be performed with the bias power smaller than that in the ME process shown in FIG. 6B.

For vertical etching of the polysilicon layer 54, the ME process substantially requires a bias power in a desired level. If the bias power is less than the desired level, directionality of ions may be deteriorated, causing lateral sides of a mask to be etched during the ME process. When the bias power decreases, the lateral sides of the mask are increasingly etched, causing a problem in ensuring mask margin, as can be seen in example FIGS. 6A and 6B. More particularly, example FIG. 6B shows a width “wb” of a valley wider than a width “wa” of a valley shown in example FIG. 6A, a margin part 80, and a height “hb” higher than a height “ha” shown in example FIG. 6A. Thus, the bias power used in the ME process may be determined such that ion directionality may be maintained during the RIE process.

Example FIGS. 7A and 7B are cross-sectional views showing a floating gate when an ME process is performed with different amounts of Cl₂ gas, respectively. An amount of the Cl₂ gas used in the ME process for fabricating the floating gate as shown in example FIG. 7A may be larger than that in the ME process as shown in example FIG. 7B.

In order to attain a desired range of etch rate in the ME process, using Cl₂ and HBr gases together may etch the polysilicon layer 54. Based on the order of reactivity in regard to halogen compounds: F>Cl>HBr, the etch rate may be reduced if only the HBr gas is used. On the other hand, a fluorine (F) based gas has relatively high reactivity, thus considerable etching of the lateral sides of the polysilicon layer may occur.

In addition, when both the Cl₂ gas and the HBr gas are used, a relative ratio of the Cl₂ gas to the HBr gas may be controlled. The reason for this is that mask loss may be greater if an amount of the Cl₂ gas is larger (as shown in example FIG. 7A) than that of the HBr gas (as shown in example FIG. 7B), although a total amount of the Cl₂ gas and the HBr gas are substantially the same in both cases shown in example FIGS. 7A and 7B.

However, if the amount of the Cl₂ gas decreases too far, the etch rate may be reduced, leading to a decrease in productivity. Therefore, a ratio of Cl₂ gas to HBr gas may be selectively determined in consideration of productivity. For example, a ratio of the Cl₂ gas to the HBr gas may, for example, be about 2:7. When the total amount of the Cl₂ gas and the HBr gas is increased, problems may occur relating to pressure control and a prolonged residence time. For example, the ratio of the Cl₂ gas to the HBr gas may be about 2:7 and the total amount of the Cl₂ gas and the HBr gas may range from between about 110 to about 250 sccm (in terms of flow rate).

Example FIG. 8 illustrates graphs for polysilicon etch rates in an ME process, wherein the horizontal axis represents measurement points in a wafer while the vertical axis represents etch rates. Example FIG. 9 illustrates measurement points on a wafer, which are shown in example FIG. 8. Each graph shown in example FIG. 8 represents etch rates obtained using the Cl₂ gas and the HBr gas in a total amount, for example, of about 150 sccm and about 220 sccm, respectively, while the ratio of the Cl₂ gas to the HBr gas was maintained at about 2:7. From example FIG. 8, it can be seen that the etch rate is not necessarily higher even with using a greater amount of gases, if the total gas amount is maintained at a desired level.

Example FIG. 10 illustrates a graph of signal intensity versus time at 426.5 nm, wherein the vertical axis represents intensity and the horizontal axis represents time. Generally an EPD waveform for chromium (Cr) may be observed at 426.5 nm. However, as illustrated in example FIG. 10, the signal intensity may drastically drop at a wavelength 80 of 426.5 nm when the tunnel oxide layer 52 is exposed by etching the polysilicon layer 54. Accordingly, the wavelength of 426.5 nm may advantageously be used in the EPD process for etching the polysilicon layer 54. For example, this result may be obtained using an etchant based on the following equation 1:

2Cl₄+Si→SiCl₄ Equation 1

Therefore, according to embodiments, the polysilicon layer 54 may be etched by the EPD process using the wavelength of 426.5 nm.

Example FIG. 11 shows a semiconductor device resulting from a method for fabricating a floating gate according to embodiments. The device may, for example, include tetraethyl orthosilicate (TEOS) 90 in an active area AA, a device isolation layer 92 and a floating gate 94.

Example FIGS. 4, 5A, 5B, 6A, 6B, 7A and 7B are views of a test wafer without any sub-layer, while example FIG. 11, in contrast, is a view of an actual wafer prepared from a process in which a sub-layer is included.

For example, using about 33 sccm of Cl₂ gas and about 117 sccm of HBr gas, a polysilicon layer may be etched by an ME process for an EPD time and about 72% (EPD+72%) over-etching time so that the floating gate 94 shown in example FIG. 11 may be formed. The EPD+72% over-etching time means 1.72 T, wherein T may be an etching time taken until the end point is determined.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. A method for fabricating a floating gate of a semiconductor device, comprising:
forming a tunnel oxide layer over a semiconductor substrate;
forming a polysilicon layer over a top surface of the tunnel oxide layer;
forming a photosensitive film pattern, which is used to fabricate a floating gate, over a top surface of the polysilicon layer;
depositing a by-product over the photosensitive pattern to form a by-product mask; and
etching the polysilicon layer, using the by-product mask as an etching mask to etch the polysilicon layer, completing fabrication of the floating gate.

2. The method according to claim 1, comprising:
etching and removing a natural oxide layer, the natural oxide layer being drained out while forming the by-product mask and remaining over the polysilicon layer.

3. The method according to claim 2, wherein the natural oxide layer is removed using argon gas.

4. The method according to claim 3, wherein the natural oxide layer is removed using at least argon gas and CF₄ gas.

5. The method according to claim 4, wherein the natural oxide layer is removed using about 30 sccm of argon gas and about 50 sccm of CF₄ gas.

6. The method according to claim 1, comprising:
determining a pressure for etching the polysilicon layer so as to increase an etch selectivity between the polysilicon layer and the by-product mask.

7. The method according to claim 1, wherein etching the polysilicon layer includes a reactive ion etching process.

8. The method according to claim 7, wherein a bias power is determined such that ion directionality is maintained during the reactive ion etching process.

9. The method according to claim 1, wherein etching the polysilicon layer includes using Cl₂ and HBr gases.

10. The method according to claim 9, wherein Cl₂ and HBr gases are used in a relative ratio of about 2:7.

11. The method according to claim 10, wherein a total amount of Cl₂ and HBr gases ranges from about 110 to about 250 sccm.

12. The method according to claim 9, wherein a total amount of Cl₂ and HBr gases ranges from about 110 to about 250 sccm.

13. The method according to claim 1, wherein etching the polysilicon layer includes an end point detection process.

14. The method according to claim 13, wherein the end point detection process detects end points at a wavelength of about 426.5 nm.

15. The method according to claim 1, wherein depositing a by-product over the photosensitive pattern to form a by-product mask includes depositing the by-product over lateral sides of the photosensitive pattern.

16. The method according to claim 10, wherein an amount of the Cl₂ gas is about 33 sccm.

17. The method according to claim 10, wherein an amount of the HBr gas is about 117 sccm.

18. The method according to claim 1, wherein etching the polysilicon layer includes over etching the polysilicon layer.

19. The method according to claim 18, wherein etching the polysilicon layer includes an end point detection process.

20. The method according to claim 18, wherein over etching the polysilicon layer includes etching for a time approximately 1.7 times greater than a time to reach a detected end point.
